(19) United States
(12) Patent Application Publication
(10) Pub. No.: US 2021/0189568 A1
(43) Pub. Date: Jun. 24, 2021

(54) COATING CARRIER ASSEMBLY AND COATING DEVICE

(71) Applicant: HON HAI PRECISION INDUSTRY CO., LTD., New Taipei (TW)

(72) Inventors: LI-SHING HOU, New Taipei (TW); QING-BO WANG, Jincheng (CN); JIE LI, Jincheng (CN)

(21) Appl. No.: 16/847,928

(22) Filed: Apr. 14, 2020

(30) Foreign Application Priority Data
Dec. 18, 2019 (CN) 201911306166.5

(51) Int. Cl. C23C 18/16

(52) U.S. Cl. CPC C23C 18/163

(57) ABSTRACT

A coating carrier assembly for supporting a to-be-plated component includes at least one supporting unit. Each of the at least one supporting unit includes a first supporting portion, a second supporting portion, and at least two ribbed plates. An annular groove is defined between the first supporting portion and the second supporting portion. The at least two ribbed plates are formed in the annular groove and connected to the first supporting portion and the second supporting portion. Each of the at least two ribbed plates comprises an overflow plating groove facing the to-be-plated component. The overflow plating groove is connected to the annular groove. The disclosure also relates to a coating device. The coating carrier assembly and the coating device can obtain a coating without shielding traces.

### FIELD

The present disclosure relates to a coating carrier assembly and a coating device using the coating carrier assembly.

### BACKGROUND

In a lens module, in order to solve imaging problems such as flare caused by stray light, a black film is often plated on a non-central area of a lens by a coating machine. The black film is ring-shaped. However, masking marks are often occurred in the black film by ribbed plate. The masking marks may cause the non-center area of the lens not to be coated with the black film, thereby failing to completely solve imaging problems such as flare caused by stray light.

Therefore, there is room for improvement in the art.

### BRIEF DESCRIPTION OF THE DRAWINGS

Implementations of the present disclosure will now be described, by way of embodiments, with reference to the attached figures.

FIG. 1 is a module view of an embodiment of a coating device according to the present disclosure.

FIG. 2 is a perspective view of a coating carrier assembly of the coating device of FIG. 1.

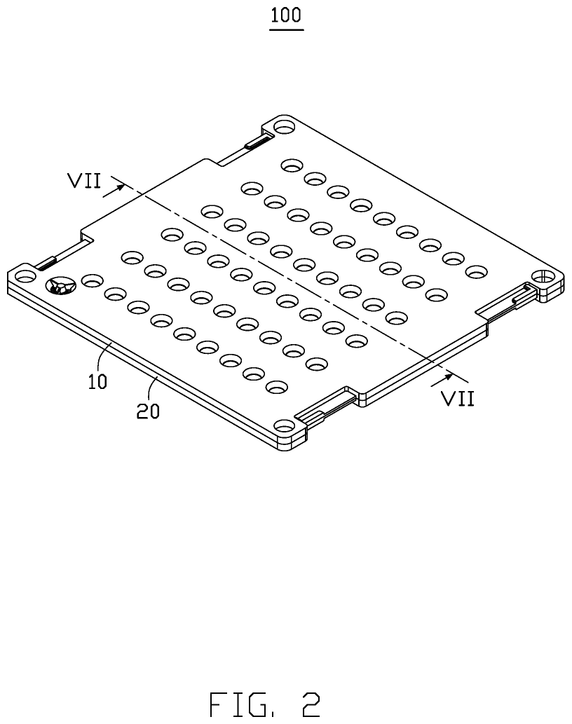

FIG. 3 is an exploded view of the coating carrier assembly of FIG. 2.

FIG. 4 is a perspective view of a supporting plate and supporting units of the coating carrier assembly of FIG. 3.

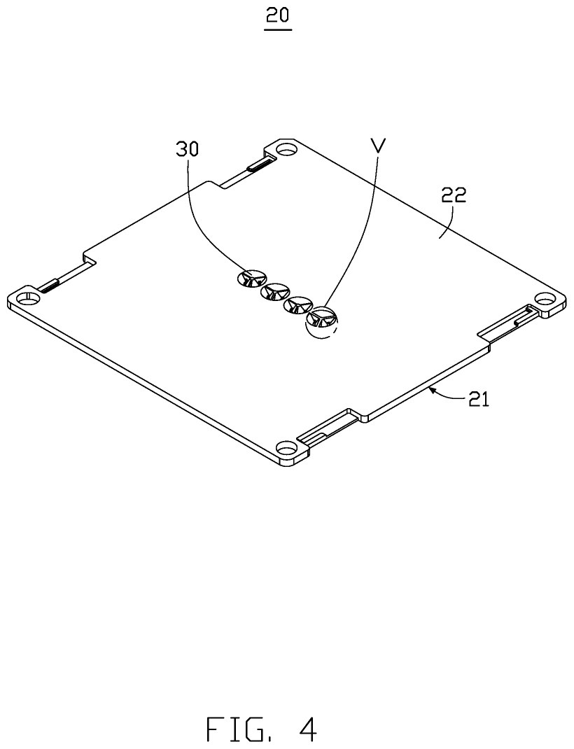

FIG. 5 is an enlarged view of a supporting unit of FIG. 3.

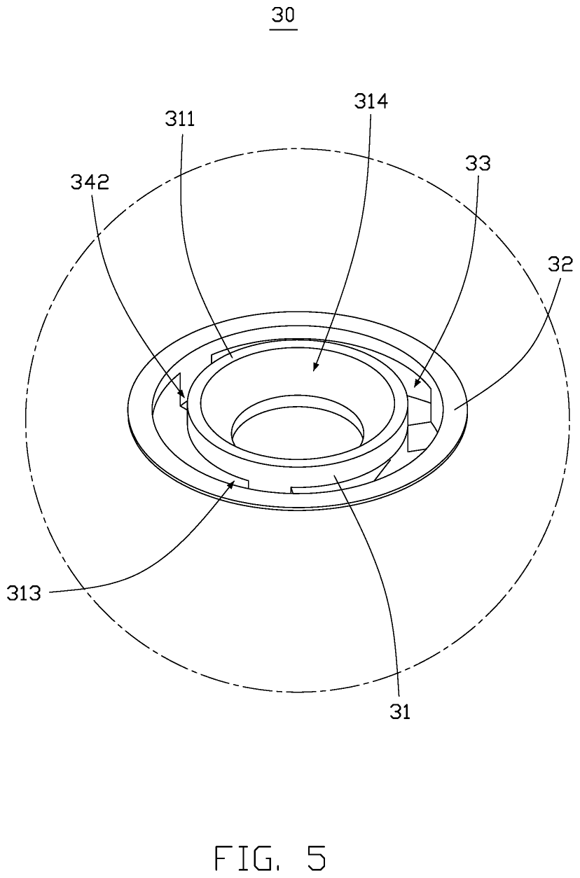

FIG. 6 is an enlarged view of a supporting unit of FIG. 4.

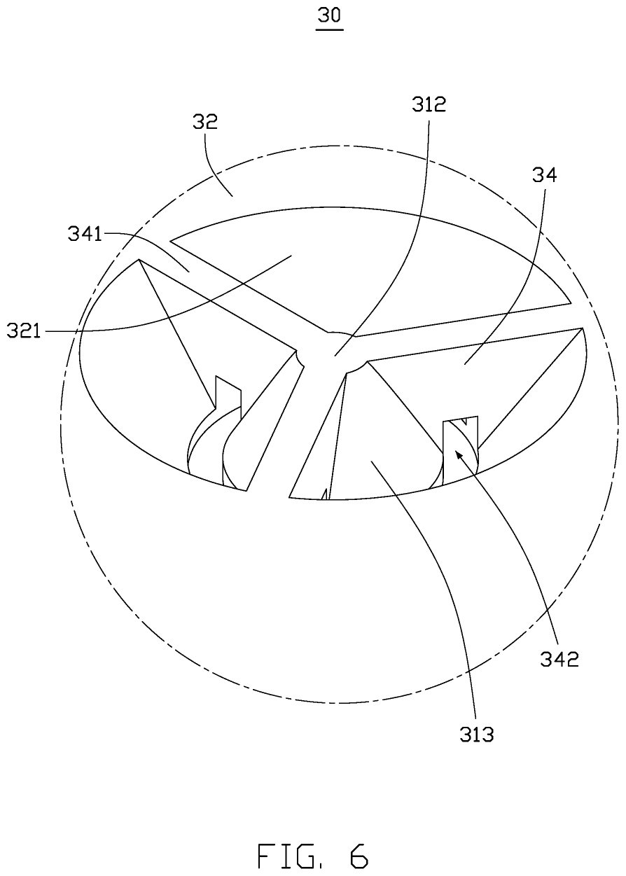

FIG. 7 is a cross-sectional view of a supporting unit of FIG. 2.

### DETAILED DESCRIPTION OF EMBODIMENTS

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure

Several definitions that apply throughout this disclosure will now be presented.

The term “comprising,” when utilized, means “including, but not necessarily limited to”; it specifically indicates open-ended inclusion or membership in the so-described combination, group, series, and the like.

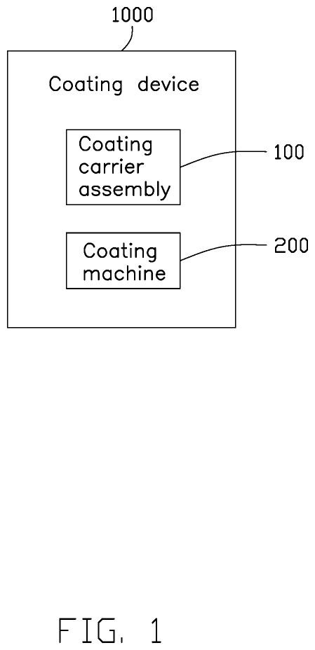

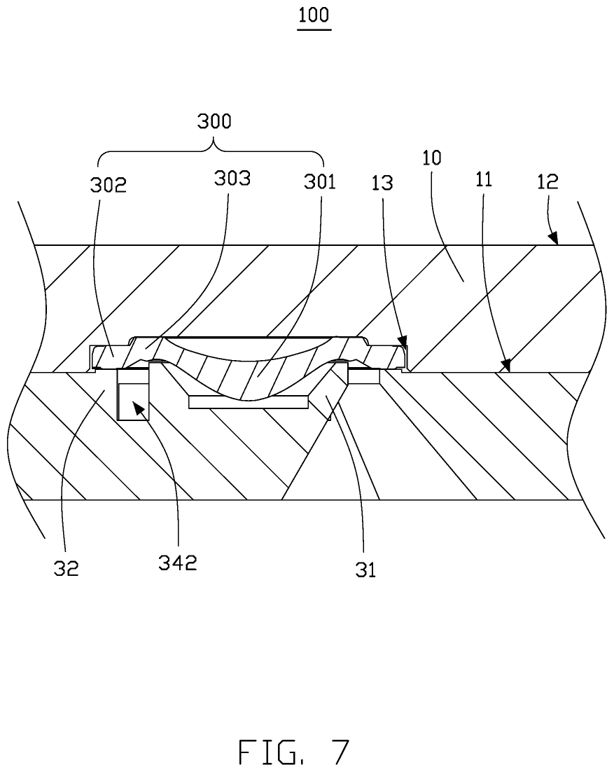

FIGS. 1 and 7 show an embodiment of a coating device 1000. The coating device 1000 is used to plate a coating on a to-be-plated component 300. The to-be-plated component 300 includes a convex portion 301 and an edge portion 302. The edge portion 302 surrounds the convex portion 301 and is connected to the convex portion 301. A coating area 303 is defined on the edge portion 302.

Referring to FIG. 1, the coating device 1000 includes a coating carrier assembly 100 and a coating machine 200. The coating machine 200 faces the coating carrier assembly 100. The coating carrier assembly 100 is used to support and fix the to-be-plated component 300. The coating machine 200 is used to form a coating on the to-be-plated component 300. In at least one embodiment, the coating is a ring-shaped black film.

The coating carrier assembly 100 includes a supporting plate 20. The to-be-plated component 300 is formed on the supporting plate 20.

The supporting plate 20 includes a first surface 21 and a second surface 22 opposite to the first surface 21.

The coating carrier assembly 100 further includes at least one supporting unit 30 formed in the supporting plate 20 in an array.

Each of the at least one supporting unit 30 includes a first supporting portion 31, a second supporting portion 32, and at least two ribbed plates 34. An annular groove 33 is defined between the first supporting portion 31 and the second supporting portion 32. The at least two ribbed plates 34 are formed in the annular groove 33 and connected to the first supporting portion 31 and the second supporting portion 32. Each of the at least two ribbed plates 34 includes an overflow plating groove 342. The overflow plating groove 342 has an opening that faces the to-be-plated component 300. The overflow plating groove 342 is connected to the annular groove 33.

The first supporting portion 31 includes a third surface 311, a fourth surface 312 opposite to the third surface 311, and an outer surface 313 connected to the third surface 311 and the fourth surface 312. A size of the third surface 311 is larger than that of the fourth surface 312. The outer surface 313 is tapered. A size of an end of the outer surface 313 facing the to-be-plated component 300 is larger than a size of an end of the outer surface 313 away from the to-be-plated component 300.

The first supporting portion 31 further includes a first receiving groove 314. The first receiving groove 314 is recessed from the third surface 311 to the fourth surface 312. The convex portion 301 of the to-be-plated component 300 is received in the first receiving groove 314.

The second supporting portion 32 includes an inner surface 321, and the inner surface 321 is tapered. A size of an end of the inner surface 321 facing the to-be-plated component 300 is smaller than a size of an end of the inner surface 321 away from the to-be-plated component 300. The outer surface 313 and the inner surface 321 define the annular groove 33. The edge portion 302 of the to-be-plated component 300 is formed on the second supporting portion 32.

In at least one embodiment, the annular groove 33 is recessed from the first surface 21 to the second surface 22. The annular groove 33 penetrates through the supporting plate 20. The first supporting portion 31 and the second supporting portion 32 are both a part of the supporting plate 20. The coating machine 200 faces the annular groove 33 and is opposite to the to-be-plated component 300.

Each of the at least two ribbed plates 34 further includes a fifth surface 341 parallel to the fourth surface 312. The fifth surface 341 is closer to the fourth surface 312 than the third surface 311. The overflow plating groove 342 is formed from a surface opposite to the fifth surface 341 toward the fifth surface 341. In at least one embodiment, the fourth surface 312 is flush with the fifth surface 341.

In at least one embodiment, a width of an end of the overflow plating groove 342 facing the to-be-plated component 300 is equal to a width of an end of the annular groove 33 facing the to-be-plated component 300. A width of an end of the overflow plating groove 342 away from the to-be-plated component 300 may be greater than or equal to or smaller than a width of the annular groove 33 facing the to-be-plated component 300.

The coating area 303 faces the annular groove 33 and the overflow plating groove 342.

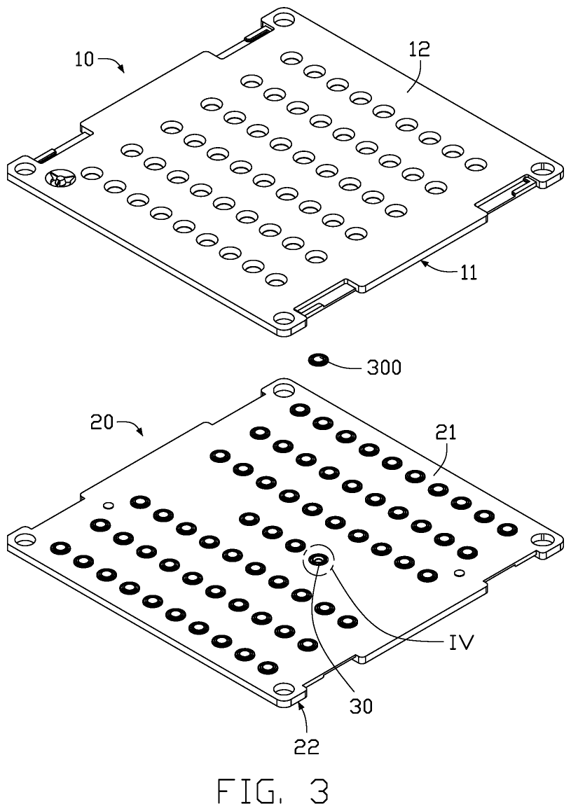

Referring to FIG. 3, the coating carrier assembly 100 further includes a cover plate 10 formed on the supporting plate 20. At least one second receiving groove 13 (shown in FIG. 7) is defined in the cover plate 10. The to-be-plated component 300 is received in the at least one second receiving groove 13. A diameter of the second receiving groove 13 is larger than an outer diameter of the annular groove 33.

The cover plate 10 includes a sixth surface 11 and a seventh surface 12 opposite to the sixth surface 11. The second receiving groove 13 is recessed from the sixth surface 11 to the seventh surface 12.

With the above configuration, the coating carrier assembly 100 and the coating device 1000 are provided with the annular groove 33 facing the coating area 303 of the to-be-plated component 300 between the first supporting portion 31 and the second supporting portion 32, and the overflow plating groove 342 facing the coating area 303 of the to-be-plated component 300 is formed on the at least two ribbed plates 34. Plating liquid from the coating machine 200 can be sprayed on the coating area 303 of the to-be-plated component 300 through the annular grooves 33 between different ribbed plates 34 and on the coating area 303 covered by the ribbed plate 34 through the overflow plating groove 342, so as to obtain a coating without shielding traces. Furthermore, the coating carrier assembly 100 and the coating device 1000 can save costs and improve imaging quality of a camera module.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A coating carrier assembly for supporting a to-be-plated component, comprising:
at least one supporting unit, wherein each of the at least one supporting unit comprises:
a first supporting portion,
a second supporting portion, wherein an annular groove is defined between the first supporting portion and the second supporting portion;
at least two ribbed plates, wherein the at least two ribbed plates are formed in the annular groove and connected to the first supporting portion and the second supporting portion; each of the at least two ribbed plates comprises an overflow plating groove facing the to-be-plated component; and the overflow plating groove is connected to the annular groove.

2. The coating carrier assembly of claim 1, wherein a width of an end of the overflow plating groove facing the to-be-plated component is equal to a width of an end of the annular groove facing the to-be-plated component.

3. The coating carrier assembly of claim 1, wherein the second supporting portion comprises an inner surface being tapered; a size of an end of the inner surface facing the to-be-plated component is smaller than a size of an end of the inner surface away from the to-be-plated component.

4. The coating carrier assembly of claim 3, wherein the first supporting portion comprises an outer surface being tapered; a size of an end of the outer surface facing the to-be-plated component is larger than a size of an end of the outer surface away from the to-be-plated component; and the annular groove is defined by the outer surface and the inner surface.

5. The coating carrier assembly of claim 1, wherein the to-be-plated component comprises a convex portion and an edge portion surrounding the convex portion; the edge portion is formed on the second supporting portion; the first supporting portion further comprises a first receiving groove; and the convex portion is received in the first receiving groove.

6. The coating carrier assembly of claim 5, wherein a coating area is defined on the edge portion; and the coating area faces the annular groove and the overflow plating groove.

7. The coating carrier assembly of claim 1, further comprising a supporting plate, wherein the at least one supporting unit is formed in the supporting plate in an array.

8. The coating carrier assembly of claim 7, wherein the supporting plate comprises a first surface and a second surface opposite to the first surface; the annular groove is recessed from the first surface to the second surface and penetrates through the supporting plate; and the first supporting portion and the second supporting portion are both a part of the supporting plate.

9. The coating carrier assembly of claim 7, further comprising a cover plate formed on the supporting plate; wherein at least one second receiving groove is defined in the cover plate; and the to-be-plated component is received in the at least one second receiving groove.

10. A coating device, comprising:
a coating carrier assembly comprising:
at least one supporting unit, wherein each of the at least one supporting unit comprises:
a first supporting portion,
a second supporting portion, wherein an annular groove is defined between the first supporting portion and the second supporting portion;
at least two ribbed plates, wherein the at least two ribbed plates are formed in the annular groove and connected to the first supporting portion and the second supporting portion; each of the at least two ribbed plates comprises an overflow plating groove facing a to-be-plated component; and the overflow plating groove is connected to the annular groove; and
a coating machine, wherein the coating machine faces the annular groove and is opposite to the to-be-plated component.

11. The coating device of claim 10, wherein a width of an end of the overflow plating groove facing the to-be-plated component is equal to a width of an end of the annular groove facing the to-be-plated component.

12. The coating device of claim 10, wherein the second supporting portion comprises an inner surface being tapered; a size of an end of the inner surface facing the to-be-plated component is smaller than a size of an end of the inner surface away from the to-be-plated component.

13. The coating device of claim 12, wherein the first supporting portion comprises an outer surface being tapered; a size of an end of the outer surface facing the to-be-plated component is larger than a size of an end of the outer surface away from the to-be-plated component; and the annular groove is defined by the outer surface and the inner surface.

14. The coating device of claim 10, wherein the to-be-plated component comprises a convex portion and an edge portion surrounding the convex portion; the edge portion is formed on the second supporting portion; the first supporting portion further comprises a first receiving groove; and the convex portion is received in the first receiving groove.

15. The coating device of claim 14, wherein a coating area is defined on the edge portion; and the coating area faces the annular groove and the overflow plating groove.

16. The coating device of claim 10, wherein the coating device further comprises a supporting plate, and the at least one supporting unit is formed in the supporting plate in an array.

17. The coating device of claim 16, wherein the supporting plate comprises a first surface and a second surface opposite to the first surface; the annular groove is recessed from the first surface to the second surface and penetrates through the supporting plate;
and the first supporting portion and the second supporting portion are both a part of the supporting plate.

18. The coating device of claim 16, wherein the coating device further comprises a cover plate formed on the supporting plate; at least one second receiving groove is defined in the cover plate; and the to-be-plated component is received in the at least one second receiving groove.
